(19) United States
(12) Patent Application Publication
(10) Pub. No.: US 2025/0355092 A1
(43) Pub. Date: Nov. 20, 2025

(54) DISTANCE MEASURING DEVICE AND COUNTER

(71) Applicant: SONY SEMICONDUCTOR SOLUTIONS CORPORATION, KANAGAWA (JP)

(72) Inventor: HIDENOBU KAKIOKA, KANAGAWA (JP)

(21) Appl. No.: 18/862,863

(22) PCT Filed: Apr. 3, 2023
(86) PCT No.: PCT/JP2023/013871

§ 371 Date: Nov. 4, 2024

(30) Foreign Application Priority Data
May 10, 2022 (JP) 2022-077584

(51) Int. Cl. G01S 7/4863; G01S 17/10

(52) U.S. Cl. CPC G01S 7/4863; G01S 17/10

(57) ABSTRACT

A gray code is controlled suitably for a range.

A distance measuring device includes one or a plurality of light emitting elements, a plurality of light receiving elements, a first counter, an encoder, a decoder, a second counter, and a distance extraction circuit. The plurality of light receiving elements receives light from the one or the plurality of light emitting elements reflected on a target. The first counter is a binary code of n digits from a first value to a second value of 2ⁿ−1−(the first value), and performs, at every predetermined time, state transition of a first binary code in which a value next to the second value is set as the first value. The encoder converts the first binary code into a gray code of n digits. The decoder acquires the second binary code of n digits from the gray code based on a light reception timing of the light receiving elements. The second counter counts the number of times of light reception in the plurality of light receiving elements corresponding to each of the second binary codes. The distance extraction circuit measures a distance to the target on the basis of a discrete value acquired by the second counter.

### TECHNICAL FIELD

The present disclosure relates to a distance measuring device and a counter.

### BACKGROUND ART

As a distance device, there is a method in which a surface emitting laser is emitted by an emission signal output from a pulse generator, light reflected from a subject is received by a pixel array, and distance measurement is performed by using a received signal and an output from the pulse generator. In this method, a time to digital converter (TDC) code can be used when a distance measurement value is acquired from an acquired histogram. As the TDC code, a gray code may be used for the purpose of avoiding a distance measurement error due to simultaneous transition of bits.

In general, this gray code has a code of 2ⁿ (n: an integer of 1 or more). Therefore, a TDC circuit using the gray code uses a counter that circulates by counting to the power of 2. However, in a case where the distance desired to be measured slightly exceeds (distance corresponding to one count value)×2ⁿ, it is necessary to expand the gray code by 1 bit and cycle the gray code by counting 2ⁿ⁺¹. It is therefore necessary to prepare a long counter that is slightly less than twice as long as a code corresponding to the distance, and problems such as an increase in power and a decrease in frame rate occur. In addition, these problems become more significant as a bit depth increases.

### CITATION LIST

### Patent Document

Patent Document 1: Japanese Patent Application Laid-Open No. 2019-197457

### SUMMARY OF THE INVENTION

### Problems to be Solved by the Invention

Therefore, the present disclosure provides gray code control suitable for a range.

### Solutions to Problems

A distance measuring device includes one or a plurality of light emitting elements, a plurality of light receiving elements, a first counter, an encoder, a decoder, a second counter, and a distance extraction circuit. The plurality of light receiving elements receives light from the one or the plurality of light emitting elements reflected on a target. The first counter is a binary code of n digits from a first value to a second value of 2ⁿ−1−(the first value), and performs, at every predetermined time, state transition of a first binary code in which a value next to the second value is set as the first value. The encoder converts the first binary code into a gray code of n digits. The decoder acquires the second binary code of n digits from the gray code based on a light reception timing of the light receiving elements. The second counter counts the number of times of light reception in the plurality of light receiving elements corresponding to each of the second binary codes. The distance extraction circuit measures a distance to the target on the basis of a discrete value acquired by the second counter.

A smaller value of the first value or the second value may be 0 or more and 2ⁿ/2−1 or less.

In a case where the first value is larger than the second value, the first counter may generate the first binary code with a value next to 2ⁿ−1 as 0.

The first counter may add one to a count value at each time of the state transition.

In a case where the first value is larger than the second value, the first counter may generate the first binary code with a value next to 0 as 2ⁿ−1.

The first counter may subtract one from a count value at each time of the state transition.

There may be further included a first value acquisition circuit that acquires 2ⁿ−1−(the second value) as the first value on a basis of the second value having been input, in which the first counter counts on the basis of the second value having been input and the first value having been acquired.

There may be further included a second value acquisition circuit that acquires the second value on a basis of the first value having been input, in which the first counter counts on the basis of the first value having been input and the second value having been acquired.

The distance extraction circuit may measure the distance to the target by a histogram having a frequency corresponding to a number of states from the first value to the second value.

The decoder may obtain a second binary code by subtracting the first value from a value obtained by converting the gray code from a binary code.

The second counter may form a histogram with a discrete value for the second binary code obtained by converting the gray code into a binary code as a discrete value for a value obtained by subtracting the first value from the second binary code.

The distance extraction circuit may accumulate a discrete value for the second binary code obtained by converting the gray code into a binary code as a histogram in the second counter, and subtract a distance corresponding to the first value from a distance extracted from the histogram.

The distance extraction circuit may accumulate a discrete value for the second binary code obtained by converting the gray code into a binary code as a histogram in the second counter, and subtract a predetermined distance from a distance extracted from the histogram.

In an embodiment, the counter includes a first counter and an encoder. The first counter is a binary code of n digits from a first value to a second value of 2ⁿ−1−(the first value), and performs, at every predetermined time, state transition of a first binary code in which a value next to the second value is set as the first value. The encoder converts the first binary code into a gray code of n digits.

The first counter may add one to a count value at each time of the state transition.

The first counter may subtract one from a count value at each time of the state transition.

There may be further included a decoder that converts the gray code output from the encoder at a timing when a predetermined control signal is received into a second binary code of n digits.

The decoder may subtract the first value from the second binary code to output.

### BRIEF DESCRIPTION OF DRAWINGS

FIG. 1 is a block diagram schematically illustrating an example of a distance measuring device according to an embodiment.

FIG. 2 is a block diagram schematically illustrating an example of a distance measurement circuit according to an embodiment.

FIG. 3 is a diagram illustrating correspondence between a binary code and a gray code.

FIG. 4 is a diagram illustrating correspondence between a binary code and a gray code according to an embodiment.

FIG. 5 is a diagram illustrating an example of a necessary TDC code according to an embodiment.

FIG. 6 is a diagram illustrating correspondence between a binary code and a gray code according to an embodiment.

FIG. 7 is a block diagram schematically illustrating an example of a distance measurement circuit according to an embodiment.

FIG. 8 is a block diagram illustrating an example of a schematic configuration of a vehicle control system.

FIG. 9 is an explanatory view illustrating an example of installation positions of an outside-vehicle information detecting section and an imaging section.

### MODE FOR CARRYING OUT THE INVENTION

Hereinafter, embodiments of the present disclosure will be described with reference to the drawings. The drawings are used for explanation, and the shape and size of each component in actual devices, the ratios of size to other configurations, and the like are not necessarily as illustrated in the drawings. In addition, since the drawings are illustrated in a simplified manner, it should be understood that configurations necessary for implementation other than those illustrated in the drawings, for example, a power supply and a buffer in a circuit diagram, are provided as appropriate.

A bit string in the present disclosure is defined as, for example, an unsigned bit string. In addition, in the present disclosure, a conversion from a binary code to a gray code and a conversion from a gray code to a binary code may be implemented by a general method or circuit.

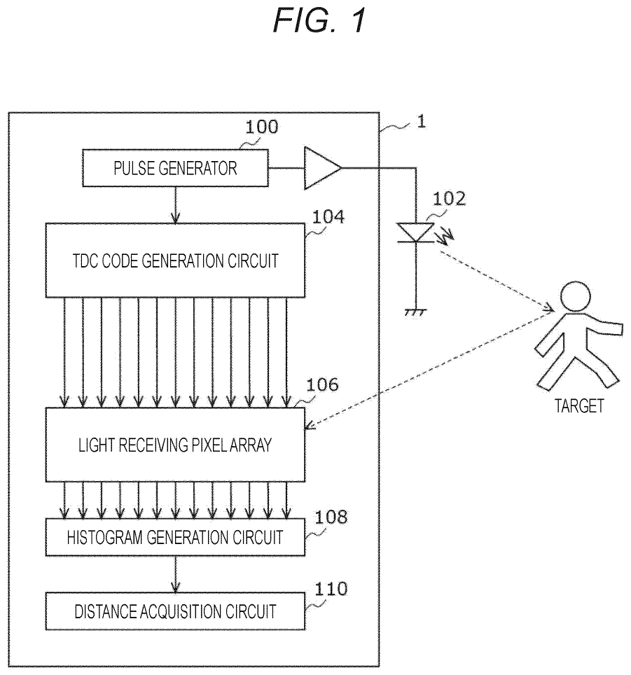

FIG. 1 is a block diagram schematically illustrating an example of a distance measuring device according to an embodiment. A distance measuring device 1 includes a pulse generator 100, a TDC code generation circuit 104, a light receiving pixel array 106, a histogram generation circuit 108, and a distance acquisition circuit 110. A light emitting element 102 is provided inside or outside the distance measuring device 1. The distance measuring device 1 is a device that measures a distance from a predetermined reference point (reference surface) to a target.

The pulse generator 100 generates and outputs a pulse signal which is a control signal for causing the light emitting element 102 to emit light.

The light emitting element 102 receives the pulse signal output from the pulse generator 100 and emits light. One or a plurality of light emitting elements 102 is provided inside or outside the distance measuring device 1. In a case where a plurality of light emitting elements 102 is provided, the light emitting elements 102 may be provided in a one-dimensional or two-dimensional array.

The TDC code generation circuit 104 generates a TDC code based on a clock signal and transmits the TDC code to each pixel in the light receiving pixel array 106. The TDC code generation circuit 104 uses, as the TDC code, for example, a gray code that does not require simultaneous transition of a plurality of bits at a timing when a numerical value transitions.

The TDC code generation circuit 104 generates the TDC code by performing a state transition of the gray code in accordance with a timing of the clock signal. The TDC code generation circuit 104 may generate the gray code with a timing when the pulse signal is received from the pulse generator 100 as an initial value, or may latch the gray code at the timing when the pulse signal is received in a latch circuit (not illustrated).

The state transition may be, for example, either incrementing (counting-up) or decrementing (counting-down). That is, a counter in the present disclosure may be in a form in which a counter value is incremented by one every time of the state transition, or may be in a form in which the counter value is decremented by one every time of the state transition.

The light receiving pixel array 106 includes, for example, light receiving pixels arranged in a two-dimensional array. Each of the light receiving pixels includes a light receiving element such as a photodiode (PD), and receives light emitted from the light emitting element 102 and reflected on the target. The light receiving pixel generates a signal by photoelectric conversion at a timing when the light receiving element receives the reflected light from the target. The light receiving pixel latches the gray code output from the TDC code generation circuit 104, and outputs the gray code at a timing when the signal is generated by photoelectric conversion to the histogram generation circuit 108.

The histogram generation circuit 108 generates a histogram for the gray code at the timing when each of the light receiving pixel arrays 106 receives light.

The distance acquisition circuit 110 acquires a distance to the target on the basis of the histogram generated by the histogram generation circuit 108. For example, the distance acquisition circuit 110 acquires time from a timing when the light emitting element 102 emits light to a timing when the light receiving pixel array 106 receives light from the gray code corresponding to a maximum value of the histogram generated by the histogram generation circuit 108, and calculates the distance to the target on the basis of the time.

By using the gray code, a transition is performed for every bit at each timing when the TDC code is incremented. Therefore, even in a case where a signal output timing of the light receiving pixel slightly changes due to some error, it is possible to maintain a state in which the error is small as compared with the binary code in which a plurality of bits simultaneously transition.

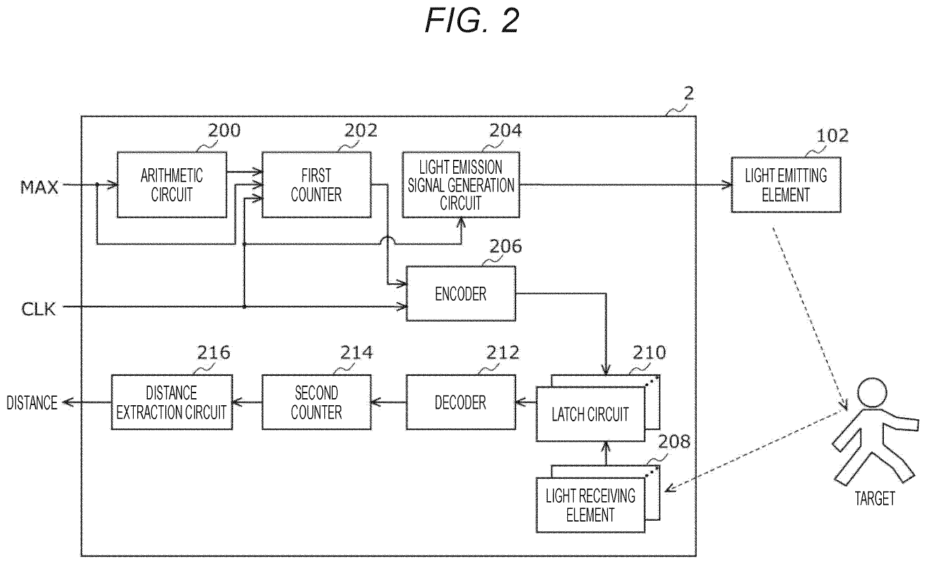

FIG. 2 is a block diagram illustrating a distance measurement circuit according to an embodiment. The distance measurement circuit 2 includes an arithmetic circuit 200, a first counter 202, a light emission signal generation circuit 204, an encoder 206, a light receiving element 208, a latch circuit 210, a decoder 212, a second counter 214, and a distance extraction circuit 216. The distance measurement circuit 2 is provided in the distance measuring device 1 in FIG. 1, and is a circuit that executes an operation of each configuration described above.

Hereinafter, the number of digits of the binary code and the gray code used in the distance measurement circuit 2 is n. That is, a decimal value indicated by the binary code and the gray code is in a range of 0 to 2ⁿ−1.

The distance measurement circuit 2 is a circuit that receives a signal MAX indicating a maximum value of the binary code and a clock signal CLK, measures the distance to the target, and outputs the distance. The signal MAX is, for example, a value of a binary code related to a maximum value of a distance to be measured. Details of the value of the signal MAX will be described later.

The distance measurement circuit 2 performs state transition of the binary code or the gray code from a first value (initial value) to a second value (final value) on the basis of the clock signal. As an example, the distance measurement circuit 2 may increment a code as a state transition. The distance measurement circuit 2 performs transition of the first value as a state subsequent to the second value. In this manner, the distance measurement circuit 2 forms a counter by circulating the gray code in the order of the first value to the first value+1 to . . . to the second value to the first value to . . . .

In a case where the first value<the second value, the distance measurement circuit 2 forms a counter by circulating the gray code from the second value to the first value. In a case where the second value<the first value, the distance measurement circuit 2 transitions the code from the first value to 2ⁿ−1, then transitions the code to 0 and circulates the code, and transitions the code from 0 to the second value, and then transitions the code to the first value. In this manner, a magnitude relationship between the first value and the second value is not limited. The transition of these discrete values is executed, for example, by the first counter 202.

As another example, the distance measurement circuit 2 may decrement the code from the second value to the first value instead of incrementing the code from the first value to the second value. In this case, the circulation from the first value to the second value can be defined in a similar manner. In addition, the circulation from 0 to 2ⁿ−1 in a case where the second value<the first value is similar. In the following description, a case where the state transition is incrementing will be described, but a similar application is possible in a case where the state transition is decrementing.

When the signal MAX is input, the arithmetic circuit 200 executes a predetermined arithmetic operation and outputs an arithmetic operation result. The signal MAX may be, for example, a value corresponding to the second value representing the final value of the code. In this case, the arithmetic circuit 200 may be a first value acquisition circuit that calculates the first value from the second value.

The first counter 202 is a circuit that generates a first binary code on the basis of the signal MAX and the signal output from the arithmetic circuit 200. The first counter 202 increments the code from a first value that is an initial value to a second value at a timing when the clock signal CLK is input (timing at every predetermined time). The first counter 202 transitions the state to the first value as a value next to the second value.

The light emission signal generation circuit 204 outputs a signal that controls the light emitting element 102 to emit light on the basis of the clock signal CLK. For example, the first counter 202 starts counting the binary code at a timing when the clock signal CLK starts to be input, and the light emission signal generation circuit 204 starts light emission at the same timing.

The timing when the input of the clock signal CLK is started may be, for example, a timing of transition from the second value to the first value. This timing may be controlled by an external circuit. By controlling the input signal in this manner, it is also possible to appropriately control the gray code in a continuously circulating state.

The encoder 206 converts an n-digit first binary code generated by the first counter 202 into an n-digit gray code. The encoder 206 converts the first binary code output from the first counter 202 into a gray code at the timing when the clock signal CLK is input.

As an example, a storage circuit may be provided in the encoder 206, the output of the first counter 202 may be held, and the first binary code held at the timing when the clock signal CLK is input may be converted into the gray code. In this case, the encoder 206 may convert a next transition state of the held binary code, which is simply a value obtained by adding 1, into a gray code and output the gray code to the latch circuit 210.

The light emitting element 102 receives a light emission signal output from the light emission signal generation circuit 204, and then, emits light. The light emitted by the light emitting element 102 is reflected by the target.

The light receiving element 208 receives the light emitted from the light emitting element 102 and reflected by the target, and photoelectrically converts the light to output a signal indicating the reception of the light. The light receiving element 208 is an element included in a plurality of pixels arranged in an array in the light receiving pixel array 106 in FIG. 1, and may be a PD, an avalanche photo diode (APD), or a single photon avalanche diode (SPAD).

The latch circuit 210 latches the gray code output from the encoder 206, and outputs a latched value to the decoder 212 at the timing when the light receiving element 208 receives the light.

As illustrated in the drawing, a plurality of light receiving elements 208 and a plurality of latch circuits 210 are provided. The latch circuit 210 may be provided so as to correspond to each of the light receiving elements 208 on a one-to-one basis. In this case, the latch circuit 210 may be included as a pixel circuit connected to the light receiving element 208.

The decoder 212 converts the n-digit gray code output from the latch circuit 210 into an n-digit second binary code and outputs the n-digit second binary code. Here, the second binary code may be, for example, a code that counts from 0 to (maximum value)−(minimum value). That is, the decoder 212 acquires the n-digit second binary code from the n-digit gray code based on a light reception timing of the light receiving element.

The second counter 214 counts the second binary code output from the decoder 212. In other words, the second counter 214 counts the number of the light receiving elements 208 that have received light at timings corresponding to the gray codes respectively.

The distance extraction circuit 216 generates a histogram on the basis of a discrete value output from the second counter 214, and extracts the distance to the target from the histogram. The distance extraction circuit 216 extracts the second binary code corresponding to, for example, a mode (mode value) in the histogram, and extracts a distance corresponding to the extracted second binary code as the distance to the target. In this manner, on the basis of the discrete value acquired from the second counter 214, the distance extraction circuit 216 acquires a binary value from the histogram in which the minimum value is 0 and the maximum value is the difference between the first value and the second value, and acquires and outputs the distance corresponding to the binary value.

Next, the transition of the binary code and the gray code in the present disclosure will be described.

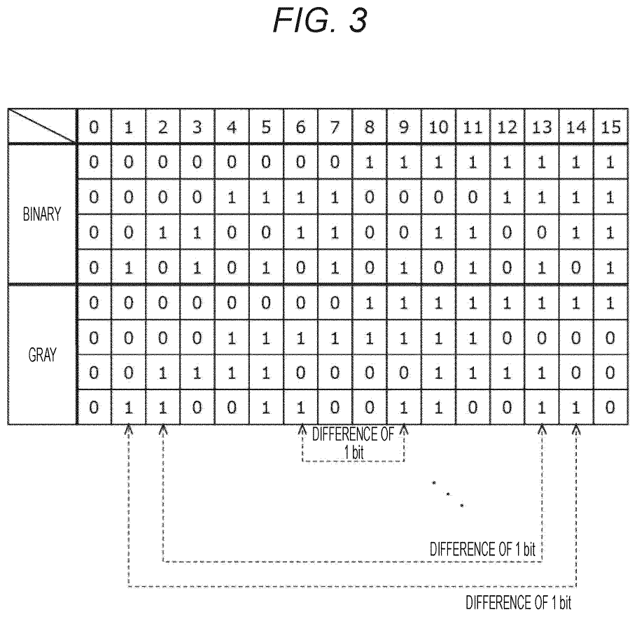

FIG. 3 is a diagram illustrating a correspondence between the binary code and the gray code in an example in which the code is 4 bits. The top row indicates a decimal value corresponding to the code. Each of the binary code and the gray code is a bit value continuous from a most significant bit (MSB) to a least significant bit (LSB) in order from an upper row.

In the binary code, a value from a minimum of 1 bit to a maximum of 4 bits (transition from 15 to 0) simultaneously changes every time the circulating discrete value increases. On the other hand, in the gray code, the value of 1 bit changes in any transition every time the circulating discrete value increases. In this manner, by using the gray code, even if the light receiving element receives light in the middle of a transition, the error of the discrete value becomes 1 at the largest. In a case where the binary code is used, the error is larger than the above. Therefore, by using the gray code in the distance measurement, an error in the measured distance can be suppressed to be small.

Here, focusing on the gray code, it can be seen that the gray code is bilaterally symmetrical with respect to an axis between 7 and 8, that is, between discrete values of 2ⁿ−1 and 2ⁿ, excluding the MSB. That is, in the gray code, only 1 bit of the MSB is different between portions where the discrete value advances from 0 to the right and from 15 to the left by the same number. Thus, it can be seen that a bit whose state changes even in a transition between the discrete values shifted from these median values by the same number to the target is 1 bit.

For example, the gray code indicating 0+1=1 is 0001, the gray code indicating 15−1=14 is 1001, and only the MSB is different. Similarly, the gray code indicating 2 is 0011, the gray code indicating 13 is 1011, and only the MSB is different. A similar application is possible to the others. Thereafter, the gray code 0101 indicating 6 and the gray code 1101 indicating 9 can be similarly represented by 1-bit transitions until only 1 bit of the MSB is different. Similarly, in a case where the bit depth increases, the difference is 1 bit of the MSB with the median value as a symmetry axis.

By setting one of these values to the first value and the other to the second value, the state of 1 bit changes in a case where the code between the first value and the second value transitions. Therefore, by defining (first value)=2ⁿ−1−(second value), the transition from the second value to the first value is represented by only a 1-bit state change. In addition, from this definition, the smaller value of the first value or the second value can be set to 0 or more and 2ⁿ−1 or less.

It should be noted that the signal MAX is the maximum value of the binary codes with which a desired distance can be counted, since the value indicating the maximum value of the distance but also a value indicating a minimum value depend on the value of the signal MAX as described above. For example, in the example of FIG. 3, in a case where the signal MAX=13 is input, since the gray code counts with values from 2 to 13, a range in which the distance can be measured is 12 stages of distances from 0 to 11.

Therefore, although not limited, the signal MAX is desirably a minimum value among values at which the maximum value of the distance to be measured can be counted. The signal MAX may have a value with a margin more or less than the minimum value at which the distance can be measured.

The signal MAX appropriately set as described above is input to the distance measurement circuit 2. Hereinafter, as a non-restrictive example, a case where the first value is smaller than the second value will be described. A case where the second value is smaller than the first value will be described later.

According to the definition described above, the arithmetic circuit 200 may set the second value as the value of the signal MAX and obtain the first value from the second value. For example, the arithmetic circuit 200 can obtain the first value by subtracting binary bits of the second value from values in which all bits are 1. As another example, the arithmetic circuit 200 can obtain the first value by obtaining an exclusive OR of a bit string in which all bits are 1 and a binary bit string of the second value.

As another example, in a case where a maximum distance desired to be measured can be represented by m steps of distances, an appropriate input value can be obtained by setting the signal MAX=2ⁿ⁻¹−1+ceil (m/2) (ceil: ceiling function). As described above, as an example, this value may have a margin such as +1.

For example, in a case where a 4-bit counter is used (n=4) and it is desired to acquire a distance in 12 stages (m=12), the signal MAX=2⁴⁻¹−1+ceil (12/2)=13 may be input to the distance measuring device 2 from the outside. Note that n may be a bit depth used for a predetermined counter, or may be determined on the basis of the value of m.

Instead of the signal MAX, m, that is, the number of stages to be counted in the TDC code may be input to the distance measurement circuit 2. The arithmetic circuit 200 may calculate, from m, the first value and the second value which are the initial value and the final value of the counter. For example, the arithmetic circuit 200 may calculate (first value)=2ⁿ⁻¹−ceil (m/2) and (second value)=2ⁿ−1−(first value)=2ⁿ⁻¹−1+ceil (m/2).

For example, in a case where it is desired to acquire the distance in 12 stages in a similar manner to the above description, the arithmetic circuit 200 can acquire (first value)=2⁴⁻¹−ceil (12/2)=2 and (second value)=2⁴⁻¹−1+ceil (m/2)=13 by operation.

In a case where m is input to the distance measurement circuit 2, as another example, the arithmetic circuit 200 can acquire (first value)=floor (2ⁿ⁻¹−m/2).

In addition, in a case where m is input in this manner, the value m of the input signal may be set to an even number. That is, in a case where m is an odd number, the signal m+1 may be input, and in a case where m is an odd number, the arithmetic circuit 200 can appropriately process the input by converting (for example, from m+1 to m) the input into an even number or by using the operation including the ceiling function described above and the like. For example, the arithmetic circuit 200 can acquire a similar result by adding 1 to the input and shifting the input to the right by 1 bit in a range in which digits do not overflow, instead of the above operation of ceil (m/2) regardless of even and odd numbers of m.

The first counter 202 generates a first binary code for performing cyclic counting on the basis of the first value and the second value set above. For example, in the example of FIG. 3, the first counter 202 generates a first binary code that starts from 2, transitions to 13, and transitions from 13 to 2. The first counter counts up to the second value as usual, and can transition from the second value to the first value by inverting bits, for example, subtracting each bit from 1 or calculating an exclusive OR of each bit and 1.

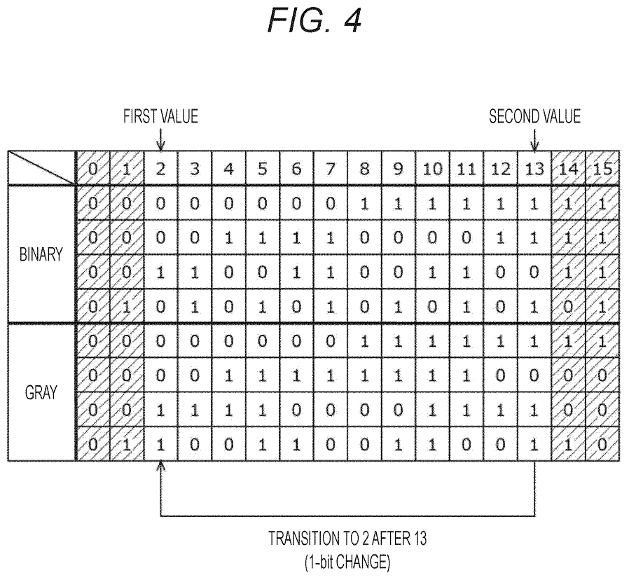

FIG. 4 is a diagram illustrating transitions of the first binary code and the gray code in a case where the first counter 202 generates the first binary code described above. The encoder 206 converts the first binary code indicating a state between 2 and 13 into a gray code. As illustrated in the drawing, the counter value of 2 is obtained after 13, and the gray code is also a 1-bit state change in this cycle. As a result, it is possible to generate a gray code having an appropriate initial value and an appropriate final value in a cycle in which only a 1-bit state change is performed in transition at any timing.

As a non-restrictive example, the decoder 212 may convert the gray code at the timing when the light receiving element 208 receives light into a second binary code indicating a range from 0 to (second value)−(first value). The decoder 212 can generate such a second binary code by subtracting the first value from the binary value obtained by converting the gray code.

The second counter 214 may count a frequency value of the light reception timing corresponding to the second binary code output from the decoder 212 described above. The distance extraction circuit 216 generates a histogram based on the second binary code obtained by converting the first value in the first binary code into 0 and the second value in the first binary code into (second value)−(first value), and extracts a mode value of the histogram to calculate the distance.

As another non-restrictive example, the decoder 212 may set, as the second binary code, a value obtained by converting the gray code at the timing when the light receiving element 208 receives light into the binary value.

In this case, as an example, the second counter 214 may count the frequency value of the light reception timing in association with a value obtained by subtracting the first value from the second binary code. As another example, the second counter 214 may count the value of the second binary code in association with the frequency value of the light reception timing. The first value may be subtracted at the timing when the distance extraction circuit 216 generates the histogram or the timing when the mode value is read from the histogram to extract the discrete value corresponding to the distance.

That is, the distance extraction circuit 216 may accumulate the discrete value for the second binary code as a histogram by the second counter 214, and measure the distance by subtracting the distance for the first value from the distance extracted from the histogram. In addition, the distance extraction circuit 216 may measure the discrete value for the second binary code by subtracting a predetermined distance from the distance extracted from the histogram by the second counter 214.

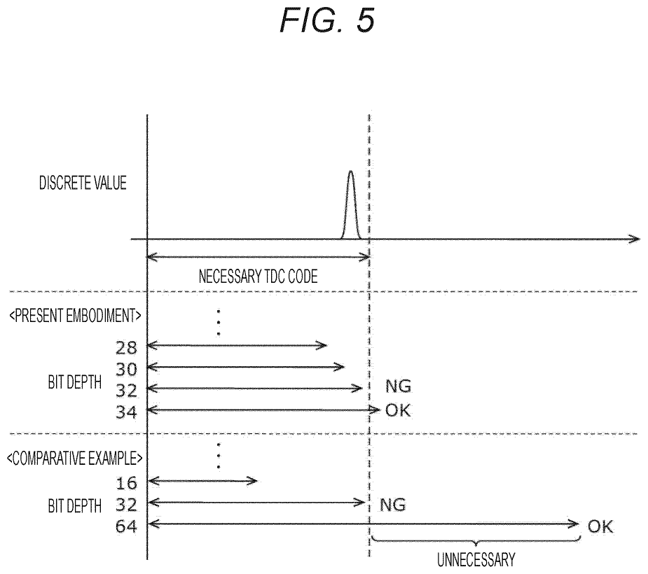

FIG. 5 is a diagram illustrating an example of a TDC code required for a distance desired to be measured according to an embodiment. The uppermost row illustrates a histogram received by the light receiving element. From this result, the width of the necessary TDC code is in a range indicated by the arrow in the drawing.

In the present embodiment, for example, m, which is an arbitrary even value, can be selected as the range of the TDC code. Therefore, as illustrated in the drawing, in a case where the width of the bit expressing m=32 stages is insufficient, a desired distance measurement result can be acquired by setting the width of the bit expressing m=34 stages.

On the other hand, in a comparative example, the range of the TDC code is selected from 2ⁿ. Therefore, it is necessary to select the bit (n=6) expressing m=64 stages. In this case, the counter value has 64 stages of 0 to 63, and the bit depth having no meaning increases. This result may become more noticeable as the bit depth, that is, the measured distance increases. This unnecessary bit may cause an increase in power consumption and a decrease in frame rate.

As described above, in the present embodiment, since the width of the TDC code represented by the gray code can be set to a multiple of two, it is possible to suppress power consumption and improve the frame rate while maintaining a small distance measurement error.

### (First Modification)

The input signal MAX may be not the maximum value of the binary code but the maximum value of the distance corresponding to the binary code. In this case, the arithmetic circuit 200 may calculate the width of the TDC code from the input maximum distance and acquire the first value and the second value. This calculation may depend on a clock frequency.

### (Second Modification)

The input signal may be a signal MIN instead of the signal MAX. The signal MIN may be a minimum value of the binary code corresponding to the distance.

In a case where the input signal is the signal MIN representing the minimum value, the arithmetic circuit 200 may be a second value acquisition circuit that calculates a second value from the first value by using the signal MIN as the first value.

### (Third Modification)

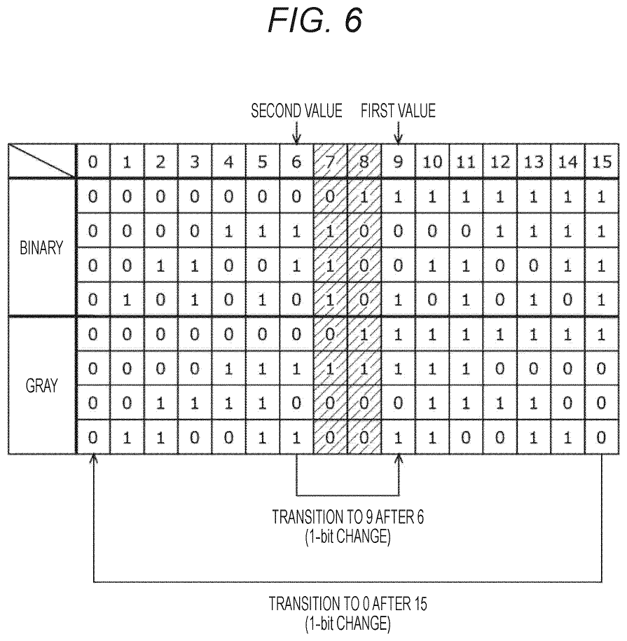

FIG. 6 is a diagram illustrating an example of a gray code in a case where the first value is larger than the second value. The first binary code is generated as a code starting from the first value 9, transitioning to 0 to 15, and then circulating to 9 when reaching 6. By converting the first binary code into a gray code, the decoder 212 can generate a gray code in which transitions at all timings are represented by 1-bit state changes.

For example, in a case where a signal input from the outside of the distance measurement circuit 2 has a required width (m) of the TDC code, such a gray code may be used. In this case, (second value)=ceil (m/2)−1, and the first value can be acquired by the arithmetic circuit 200, similarly to the above-described embodiment.

Thus, a similar effect can be obtained by omitting the central portion of the discrete value instead of omitting both ends of the discrete value.

Note that, in the above embodiment and modifications, there is a portion described by using a case where n is 4, but the present invention is not limited thereto, and a value of arbitrary n, that is, selection can be made such that the maximum width of the TDC code is 2ⁿ.

In the embodiment described above, a case where the counter is used in the distance measurement circuit 2 has been described, but the counter of the present disclosure can be used for a counter using a gray code. The counter may include, for example, a first counter and an encoder.

The first counter is a binary code of n digits from the first value to the second value of 2ⁿ−1−(first value), and performs, at every predetermined time, state transition of (increments or decrements) the first binary code in which a value next to the second value is set as the first value. The encoder converts the first binary code into an n-digit gray code. This output of the encoder can be used for counting.

In addition, the counter may include the decoder described above.

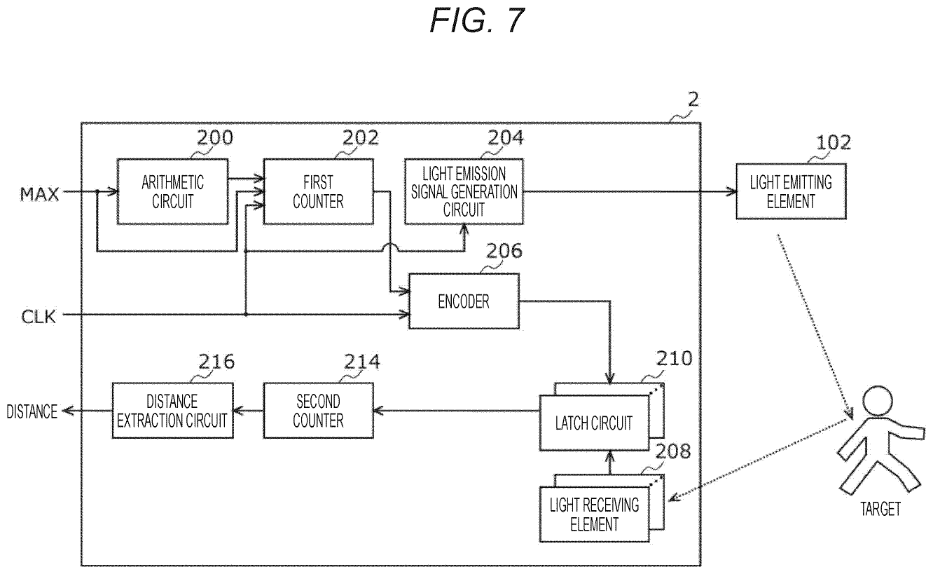

FIG. 7 is a block diagram schematically illustrating a distance measurement circuit 2 according to another embodiment. The distance measurement circuit 2 is not required to include the decoder. Without the decoder, a histogram of the gray code based on the output from the light receiving element 208 may be generated, and the distance extraction circuit 216 may appropriately convert the gray code to acquire distance information via the binary code or directly not via the binary code.

In this manner, it is also possible to perform distance measurement without the decoder. In this case, by using encoding of the present disclosure, it is also possible to appropriately implement counting with a small error without increasing power consumption.

### Application Examples

The technology of the present disclosure can be applied to various products. For example, the technology of the present disclosure may also be implemented as a device mounted on any kind of mobile body such as an automobile, an electric automobile, a hybrid electric automobile, a motorcycle, a bicycle, a personal mobility, an airplane, a drone, a ship, a robot, a construction machine, an agricultural machine (tractor), or the like.

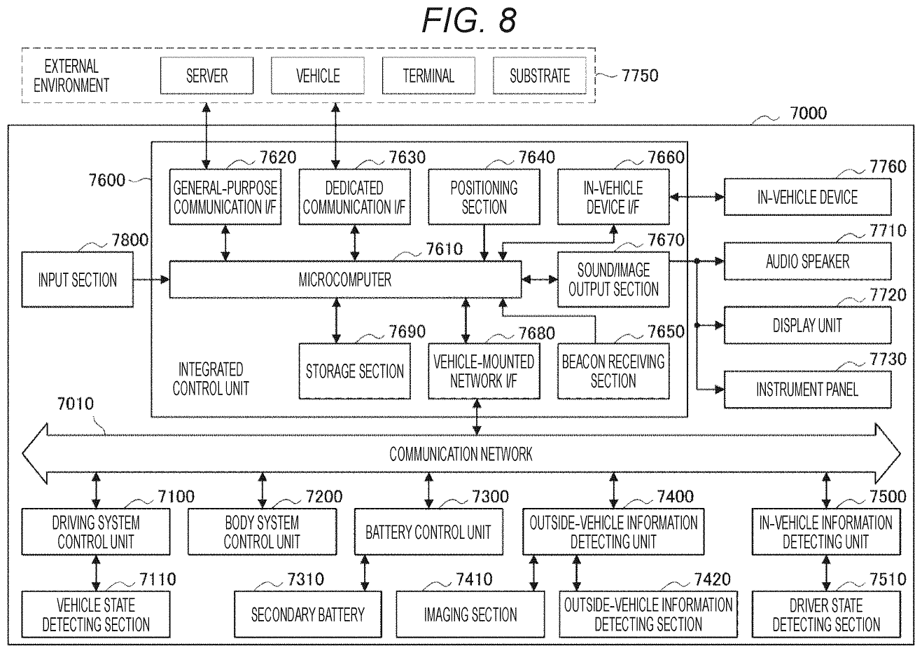

FIG. 8 is a block diagram illustrating a schematic configuration example of a vehicle control system 7000 as an example of a mobile body control system to which the technology of the present disclosure is applied. The vehicle control system 7000 includes a plurality of electronic control units connected to each other via a communication network 7010. In the example illustrated in FIG. 8, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. In FIG. 8, a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690 are illustrated as a functional configuration of the integrated control unit 7600. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

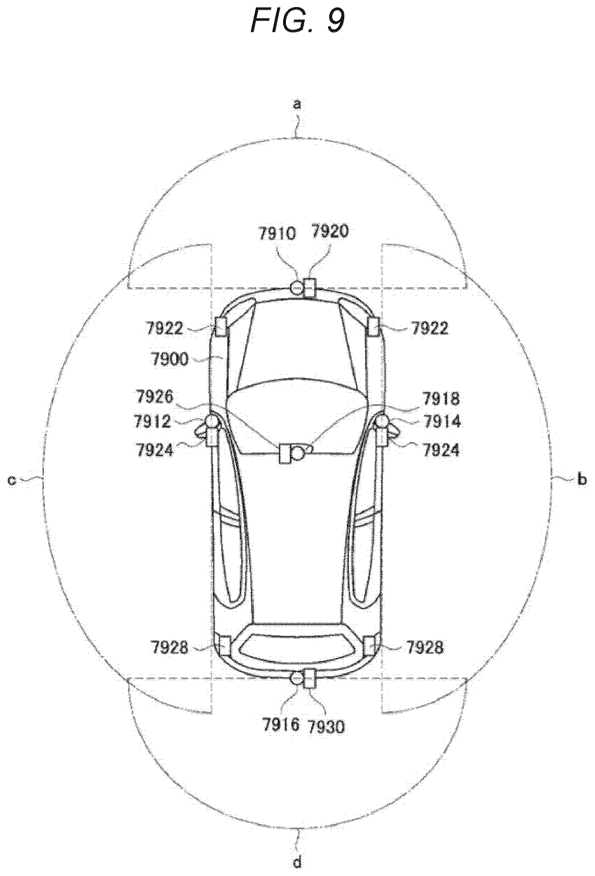

Here, FIG. 9 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 9 illustrates an example of the imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Referring back to FIG. 8, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEE 7609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 8, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that, in the example illustrated in FIG. 8, at least two control units connected via the communication network 7010 may be integrated as one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for implementing each function of the distance measuring device 1 or the distance measurement circuit 2 according to the present embodiment described with reference to FIGS. 1 to 7 can be mounted on any control unit or the like. In addition, a computer-readable recording medium in which such a computer program is stored can be provided. The recording medium is, for example, a magnetic disk, an optical disk, a magneto-optical disk, a flash memory, or the like. In addition, the computer program described above may be distributed via, for example, a network without using a recording medium.

In the vehicle control system 7000 described above, the distance measuring device 1 or the distance measurement circuit 2 according to the present embodiments described with reference to FIGS. 1 to 7 can be applied to the integrated control unit 7600 of the application example illustrated in FIG. 8.

In addition, at least some constituent elements of the distance measuring device 1 or the distance measurement circuit 2 described with reference to FIGS. 1 to 7 and the like may be implemented in a module (for example, an integrated circuit module including one die) for the outside-vehicle information detecting unit 7400, the imaging section 7410, or the outside-vehicle information detecting section 7420, or the positioning section 7640 illustrated in FIG. 8.

The embodiments described above may have the following forms.

(1)

A distance measuring device including
a plurality of light receiving elements that receives light emitted from one or a plurality of light emitting elements and reflected on a target,
a first counter that performs, at every predetermined time, state transition of a first binary code that is a binary code of n digits from a first value to a second value that is 2ⁿ−1−(the first value) and in which a value next to the second value is set as the first value,
an encoder that converts the first binary code into a gray code of n digits,
a decoder that acquires a second binary code of n digits from the gray code based on a light reception timing of the light receiving elements,
a second counter that counts the number of times of light reception of the plurality of light receiving elements corresponding to each of the second binary codes, and
a distance extraction circuit that measures a distance to the target on the basis of a discrete value acquired by the second counter.
   (2)

The distance measuring device according to (1), in which
a smaller value of the first value or the second value is 0 or more and 2ⁿ/2−1 or less.
   (3)

The distance measuring device according to (2), in which
in a case where the first value is larger than the second value,
   the first counter generates the first binary code with a value next to 2ⁿ−1 as 0.
      (4)

The distance measuring device according to (3), in which
the first counter adds one to a count value at each time of the state transition.
   (5)

The distance measuring device according to (2), in which
in a case where the first value is larger than the second value,
   the first counter generates the first binary code with a value next to 0 as 2ⁿ−1.
      (6)

The distance measuring device according to (5), in which
the first counter subtracts one from a count value at each time of the state transition.
   (7)

The distance measuring device according to any of (1) to (6), further including
a first value acquisition circuit that acquires 2ⁿ−1−(the second value) as the first value on the basis of the second value having been input, in which
the first counter counts on the basis of the second value having been input and the first value having been acquired.
   (8)

The distance measuring device according to any of (1) to (6), further including
a second value acquisition circuit that acquires the second value on a basis of the first value having been input, in which
the first counter counts on the basis of the first value having been input and the second value having been acquired.
   (9)

The distance measuring device according to any of (1) to (8), in which
the distance extraction circuit measures the distance to the target by a histogram having a frequency corresponding to the number of states from the first value to the second value.
   (10)

The distance measuring device according to (9), in which
the decoder obtains a second binary code by subtracting the first value from a value obtained by converting the gray code from a binary code.
   (11)

The distance measuring device according to (9), in which
the second counter forms a histogram with a discrete value for the second binary code obtained by converting the gray code into a binary code as a discrete value for a value obtained by subtracting the first value from the second binary code.
   (12)

The distance measuring device according to (9), in which
the distance extraction circuit accumulates a discrete value for the second binary code obtained by converting the gray code into a binary code as a histogram in the second counter, and subtracts a distance corresponding to the first value from a distance extracted from the histogram.
   (13)

The distance measuring device according to (9), in which
the distance extraction circuit accumulates a discrete value for the second binary code obtained by converting the gray code into a binary code as a histogram in the second counter, and subtracts a predetermined distance from a distance extracted from the histogram.
   (14)

A counter including
a first counter that performs, at every predetermined time, state transition of a first binary code that is a binary code of n digits from a first value to a second value that is 2ⁿ−1−(the first value) and in which a value next to the second value is set as the first value, and
an encoder that converts the first binary code into a gray code of n digits.
   (15)

The counter according to (14), in which
the first counter adds one to a count value at each time of the state transition.
   (16)

The counter according to (14), in which
the first counter subtracts one from a count value at each time of the state transition.
   (17)

The counter according to (14), further including
a decoder that converts the gray code output from the encoder at a timing when a predetermined control signal is received into a second binary code of n digits.
   (18)

The counter according to (17), in which
the decoder subtracts the first value from the second binary code to output.

Aspects of the present disclosure are not limited to the embodiments described above, and include various conceivable modifications. The effects of the present disclosure are not limited to the contents described. The constituent elements in each of the embodiments may be appropriately combined and applied. That is, various additions, modifications, and partial deletions can be made without departing from the conceptual idea and gist of the present disclosure derived from the contents defined in the claims and equivalents and the like thereof.

### REFERENCE SIGNS LIST

1 Distance measuring device
100 Pulse generator
102 Light emitting element
104 TDC code generation circuit
106 Light receiving pixel array
108 Histogram generation circuit
110 Distance acquisition circuit
2 Distance measurement circuit
200 Arithmetic circuit
202 First counter
204 Light emission signal generation circuit
206 Encoder
208 Light receiving element
210 Latch circuit
212 Decoder
214 Second counter
216 Distance extraction circuit

1. A distance measuring device comprising:
a plurality of light receiving elements that receives light emitted from one or a plurality of light emitting elements and reflected on a target;
a first counter that performs, at every predetermined time, state transition of a first binary code that is a binary code of n digits from a first value to a second value that is 2ⁿ−1−(the first value) and in which a value next to the second value is set as the first value;
an encoder that converts the first binary code into a gray code of n digits;
a decoder that acquires a second binary code of n digits from the gray code based on a light reception timing of the light receiving elements;
a second counter that counts a number of times of light reception of the plurality of light receiving elements corresponding to each of the second binary codes; and
a distance extraction circuit that measures a distance to the target on a basis of a discrete value acquired by the second counter.

2. The distance measuring device according to claim 1, wherein
a smaller value of the first value or the second value is 0 or more and 2ⁿ/2−1 or less.

3. The distance measuring device according to claim 2, wherein
in a case where the first value is larger than the second value,
the first counter generates the first binary code with a value next to 2ⁿ−1 as 0.

4. The distance measuring device according to claim 3, wherein
the first counter adds one to a count value at each time of the state transition.

5. The distance measuring device according to claim 2, wherein
in a case where the first value is larger than the second value,
the first counter generates the first binary code with a value next to 0 as 2ⁿ−1.

6. The distance measuring device according to claim 5, wherein
the first counter subtracts one from the count value at each time of the state transition.

7. The distance measuring device according to claim 1, further comprising
a first value acquisition circuit that acquires 2ⁿ−1−(the second value) as the first value on a basis of the second value having been input, wherein
the first counter counts on a basis of the second value having been input and the first value having been acquired.

8. The distance measuring device according to claim 1, further comprising
a second value acquisition circuit that acquires the second value on a basis of the first value having been input, wherein
the first counter counts on a basis of the first value having been input and the second value having been acquired.

9. The distance measuring device according to claim 1, wherein
the distance extraction circuit measures the distance to the target by a histogram having a frequency corresponding to a number of states from the first value to the second value.

10. The distance measuring device according to claim 9, wherein
the decoder obtains a second binary code by subtracting the first value from a value obtained by converting the gray code from a binary code.

11. The distance measuring device according to claim 9, wherein
the second counter forms a histogram with a discrete value for the second binary code obtained by converting the gray code into a binary code as a discrete value for a value obtained by subtracting the first value from the second binary code.

12. The distance measuring device according to claim 9, wherein
the distance extraction circuit accumulates a discrete value for the second binary code obtained by converting the gray code into a binary code as a histogram in the second counter, and subtracts a distance corresponding to the first value from a distance extracted from the histogram.

13. The distance measuring device according to claim 9, wherein
the distance extraction circuit accumulates a discrete value for the second binary code obtained by converting the gray code into a binary code as a histogram in the second counter, and subtracts a predetermined distance from a distance extracted from the histogram.

14. A counter comprising:
a first counter that performs, at every predetermined time, state transition of a first binary code that is a binary code of n digits from a first value to a second value that is 2ⁿ−1−(the first value) and in which a value next to the second value is set as the first value; and
an encoder that converts the first binary code into a gray code of n digits.

15. The counter according to claim 14, wherein
the first counter adds one to a count value at each time of the state transition.

16. The counter according to claim 14, wherein
the first counter subtracts one from a count value at each time of the state transition.

17. The counter according to claim 14, further comprising
a decoder that converts the gray code output from the encoder at a timing when a predetermined control signal is received into a second binary code of n digits.

18. The counter according to claim 17, wherein
the decoder subtracts the first value from the second binary code to output.
